(19) United States
(12) Patent Application Publication
(10) Pub. No.: US 2025/0309571 A1
(43) Pub. Date: Oct. 2, 2025

(54) LIQUID METAL SOCKET INTERCONNECTS WITH LITHOGRAPHICALLY DEFINED SOCKET CONTACT PINS

(71) Applicant: Intel Corporation, Santa Clara, CA (US)

(72) Inventors: Karumbu Nathan Meyyappan, Portland, OR (US); Pooya Tadayon, Portland, OR (US)

(73) Assignee: Intel Corporation, Santa Clara, CA (US)

(21) Appl. No.: 18/622,782

(22) Filed: Mar. 29, 2024

(51) Int. Cl. H01R 12/71; H01L 21/48; H01L 23/32; H01L 23/498; H01R 12/70; H01R 13/03; H01R 43/16; H05K 1/18

(52) U.S. Cl. CPC H01R 12/716; H01L 21/4846; H01L 23/32; H01L 23/49811; H01L 23/49833; H01L 23/49866; H01R 12/7005; H01R 12/718; H01R 13/03; H01R 43/16; H05K 1/181; H05K 2201/10189

(57) ABSTRACT

In one embodiment, a liquid metal (LM)-compatible socket includes lithographically-defined metal pins extending from the socket. The distance between centers of neighboring first metal pins may be less than 500 um. The socket may also include lithographically-defined alignment pins.

### BACKGROUND

Liquid metal (LM) interconnect architectures may utilize Gallium (Ga) or Ga alloy liquid metals to provide separable and reusable interconnections for integrated circuit devices, e.g., in lieu of traditional solder-based interconnection technologies (e.g., ball grid arrays) that are substantially permanent in their current implementations.

### BRIEF DESCRIPTION OF THE DRAWINGS

FIGS. 1A-1B illustrate an example integrated circuit device assembly that utilizes a liquid metal (LM) socket interconnect in accordance with embodiments of the present disclosure.

FIGS. 2A-2F illustrate an example lithography-based process of manufacturing LM-based interconnect components in accordance with embodiments of the present disclosure.

FIGS. 3A-3B illustrate the socket-pin interface for stitched contact pins and lithographically-defined contact pins, respectively.

FIG. 4 illustrates an alternate example of an integrated circuit device assembly in accordance with embodiments of the present disclosure.

FIG. 5 is a top view of a wafer and dies that may be included in a microelectronic assembly, in accordance with any of the embodiments disclosed herein.

FIG. 6 is a cross-sectional side view of an integrated circuit device that may be included in a microelectronic assembly, in accordance with any of the embodiments disclosed herein.

FIG. 7 is a block diagram of an example electrical device that may include a microelectronic assembly, in accordance with any of the embodiments disclosed herein.

### DETAILED DESCRIPTION

Embodiments herein include integrated circuit device assemblies that utilize liquid metal (LM)-based interconnects with lithographically defined socket pins. The LM-based interconnects may implement wells (which may also referred to as reservoirs) that include a LM alloy, e.g., a Gallium (Ga)-based LM alloy, between the backside of an integrated circuit package and a socket of a circuit board (e.g., a main board or motherboard). The LM-based interconnect can provide a low insertion force and low contact resistance interface between pads of the package substrate and contacts (e.g., metal pins) of the socket. In certain architectures, the LM is filled into wells that are attached to an integrated circuit package, e.g., in an interposer-like device. A socket may have pins that are inserted into the wells when the package is attached, causing the pins and LM to be in physical contact (and thus, electrical connection) with one another. The package can later be removed to allow for attachment to another socket, or to allow for another package to be attached to the same socket (e.g., when the package is defective).

Current LM-based interconnects are designed for pin-to-pin distances (which may be referred to as “pitch”) of 800 um or more, whereas solder-based interconnects can be designed with smaller pitch (e.g., 600 um or less). More particularly, the pitch may refer to the distance between centers of neighboring pins (or corresponding LM wells). As LM-based interconnects can provide advantages to the traditional solder-based interconnects, it is thus desirable to design such interconnects with smaller pitch. The smaller pitch LM-based interconnects would utilize smaller LM wells, which would lead to less LM usage overall and thus, lower costs.

However, current manufacturing methods for LM-based interconnect sockets limits any further pitch reduction. For example, current methods use pins that of approximately 100 um diameter that fit inside a well that is approximately 400 um in diameter. This difference in size between the pin and the well diameters can ensure that the pin does not contact the wall of the well, which could result in damaging the pin. In addition, this difference can help to provide a buffer for variances in the placement of the pins, which are typically inserted into the socket via a “stitching” process that has a wide tolerance for the pin tip true placement position (as current limits for the pin true position may be +/−100 um, for example, which can drive a large portion of pin placement errors that can occur during manufacturing). Accordingly, reducing the pin pitch below 800 um could result in higher socket rejects, thereby raising the overall costs of producing the LM-compatible sockets.

Embodiments of the present disclosure may avoid these or other issues by fabricating LM-compatible socket pins and their corresponding wells using a lithography-based process that can reduce or remove the pin placement accuracy issues that are associated with typical pin stitching and also allow for lower pin pitch and smaller well sizes in LM-based interconnects. For instance, in an example 500 um pitch design, LM well diameters might be approximately 200-250 um (as compared with current diameters of approximately 400 um) and the pins may have a diameter of approximately 100 um and a height of approximately 500 um. Certain embodiments may also incorporate alignment pins into the socket that are also lithographically defined. These alignment pins can help to reduce or eliminate errors between corner alignment pins that align an integrated circuit device package to the socket, as alignment pins can contribute to additional errors for the true position. In addition, the pin grid array can be built off interposers of materials other than the traditional liquid crystal polymer (LCP)-based sockets. For example, some embodiments may fabricate the pin grid array on an epoxy-based substrate material, such as FR4 (a silicon glass fiber woven epoxide matrix composite material).

Embodiments produced by the lithography-based processes as described herein may provide one or more advantages over current LM-based interconnects or traditional solder-based interconnects. As one example, certain embodiments may be able to use many more pin materials that can be more compatible with the Gallium-based LM that is used. For instance, certain metals that are used currently might be at risk for corrosion when exposed to the LM; however, certain materials described herein can be used to form pins that have reduced corrosion risk over the current materials used in these LM-compatible sockets. As another example, the use of new substrate materials can open up the ability to etch conductive traces or planes into the socket body itself, which can add opportunities to optimize the socket design for high-speed performance applications.

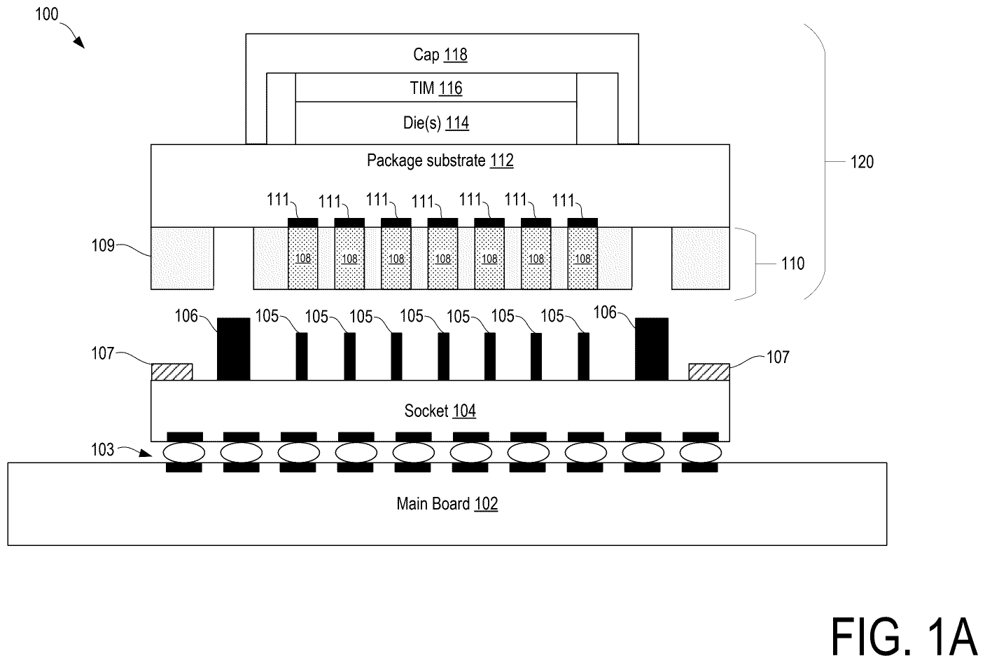

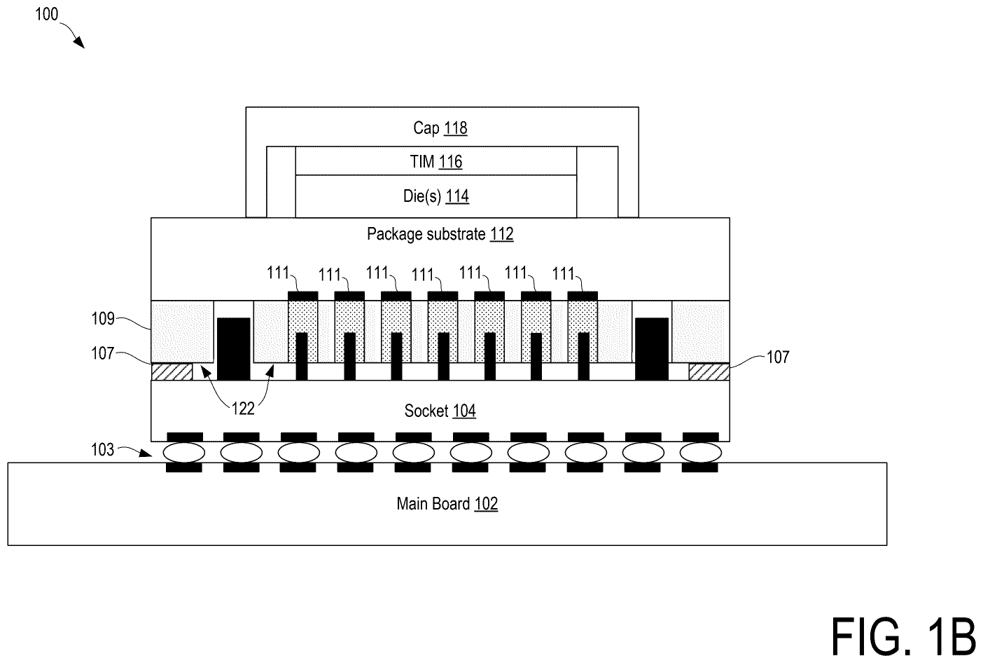

FIGS. 1A-1B illustrate an example integrated circuit device assembly 100 that utilizes a liquid metal (LM) interconnect in accordance with embodiments of the present disclosure. In the example shown, the assembly 100 includes a main board 102, which may be a motherboard, system board, etc. The main board 102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the main board 102. In other embodiments, the main board 102 may be or include a non-PCB substrate.

A LM-compatible socket 104 is coupled to the main board 102 via solder bumps 103. The solder bumps 103 are connected between conductive contacts of the main board 102 and the socket 104, as shown. The solder bumps 103 may be formed using Tin or any other suitable solder material. In some embodiments, the LM-compatible socket 104 may be coupled to the main board 102 via another mechanism than solder bumps. The socket 104 may include metal traces, vias, or metallization layers to interconnect the pins 105 with the conductive contacts on the opposite side of the socket 104.

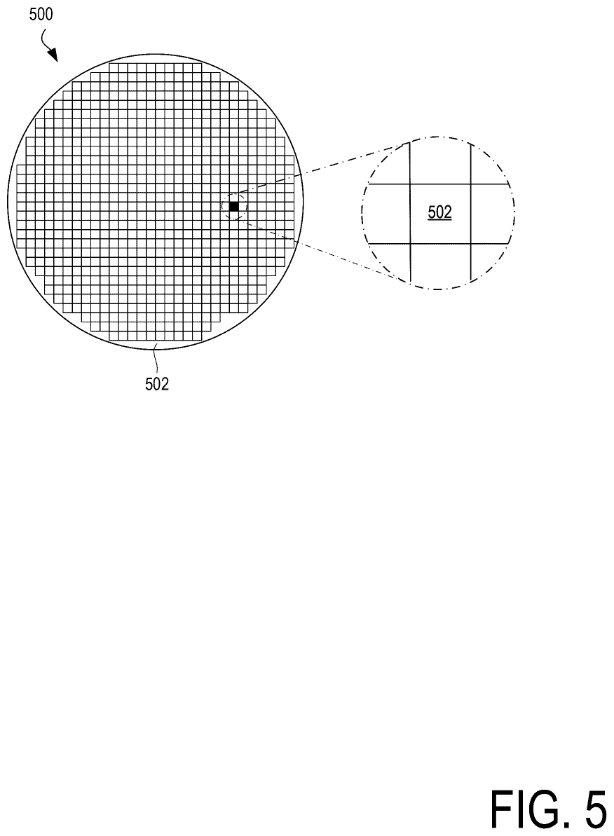

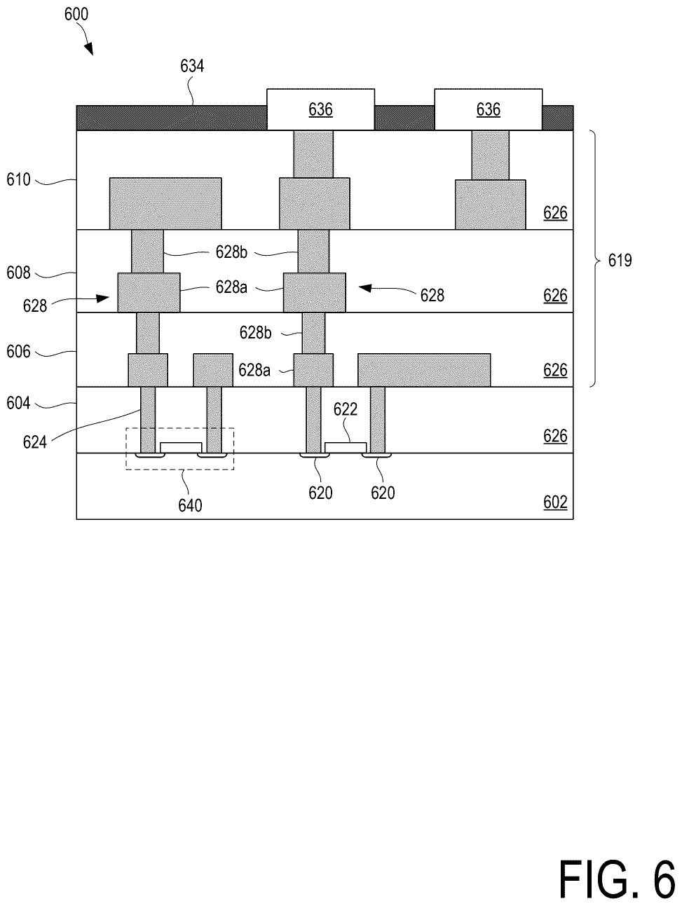

The assembly 100 also includes an integrated circuit device package 120 that includes a package substrate 112, one or more integrated circuit dies 114 on the package substrate 112, a thermal interface material (TIM) 116 on the die(s) 114, and a cap 118 enclosing the die(s) 114 and TIM 116 on the top surface of the package substrate 112. The die(s) 114 may be a packaged or unpacked integrated circuit product that includes one or more integrated circuit dies (e.g., the die 502 of FIG. 5, the integrated circuit device 600 of FIG. 6) and/or one or more other suitable components. The die(s) 114 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the die(s) 114 can comprise one or more additional active or passive devices such as capacitors, decoupling capacitors, resistors, inductors, fuses, diodes, transformers, sensors, electrostatic discharge (ESD) devices, and memory devices. In addition to comprising one or more processor units, the die(s) 114 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where the die(s) 114 comprises multiple integrated circuit dies, interconnections between the dies can be provided by the package substrate, one or more silicon interposers, one or more silicon bridges embedded in the package substrate (such as Intel® embedded multi-die interconnect bridges (EMIBs)), or combinations thereof.

The package 120 also includes an interposer 110, which includes a layer 109 with holes therein that define LM reservoirs or wells 108 (in which a LM resides, e.g., a Ga-based LM) around respective conductive contacts 111 of the substrate 112. As used herein, an opening, hole, or well being “defined around” a conductive contact may refer to the opening's defining structures being formed adjacent to the conductive contact such that the conductive contact is accessible via the opening, hole, or well. This can include the structures of the opening, hole, or well surrounding all or a portion of the conductive contact. For instance, in the example shown, the walls of the wells 108 are defined around the conductive contacts 111 such that the conductive contacts 111 would be accessible from within the wells 108, e.g., LM within the wells can be in physical contact with the conductive contacts 111 when inside the wells 108 as shown. In some embodiments, the wells 108 may be defined around the conductive contacts 111 such that the entire conductive contact 111 is accessible from within the well 108 (e.g., a cross-sectional area of the conductive contact 111 is smaller or equal to the cross-sectional area of the well 108), while in other embodiments, the wells may be defined around the conductive contacts 111 such that only a portion of the conductive contact 111 is accessible from within the well 108 (e.g., a cross-sectional area of the conductive contact 111 is larger than the cross-sectional area of the well 108).

In some embodiments, the interposer 110 may also include a barrier layer to prevent the LM from leaving the wells 108. The barrier layer may be a polymer material, such as a self-healing polymer. The package substrate 112 includes a set of conductive contacts 111 formed on the backside of the substrate, i.e., on the side opposite from the die(s) 114. The conductive contacts 111 may be in the form of metal pads, and may allow for electrical connections between the main board 102 and the die(s) 114, via the socket 104, the LM in the wells 108 of the interposer 110, and traces within the package substrate 112. In addition, there may be solder bumps on the conductive contacts 111 and in contact with the LM in the wells 108 of the interposer 110.

As shown, the LM-compatible socket 104 includes a set of contact pins 105 extending from the socket 104, as well as alignment pins 106, which are wider and taller than the contact pins 105 and aid in alignment of the package 120 and socket 104 during attachment. In the example shown, the alignment pins 106 are outside the area in which the contact pins 105 reside; however, other embodiments may place the alignment pins 106 in other locations. The contact pins 105 enable an electrical connection between the main board 102 and the die(s) 114 through the LM in wells 108, conductive contacts 111, and conductive paths in the package substrate 112. The ends of the contact pins 105 may pierce a barrier of the interposer 110, causing the contact pins 105 to be in physical contact with the LM in the wells 108, and to thus be in electrical contact with the conductive contacts 111 of the package substrate 112 as shown in FIG. 1B. Accordingly, the die(s) 114 may be in electrical contact with the main board 102. The socket 104 may have a seal material 107 formed on an outer portion, e.g., as shown, which can help to seal the inner volume 122 of the assembly 100 when the package 120 is attached to the socket 104 (e.g., to prevent moisture from entering the inner volume 122).

In embodiments herein, the pins 105, 106 may have any suitable cross-section, e.g., the pins 105, 106 may have a generally circular, rectangular, square, or other cross-section. Moreover, the cross-sections of the pins 105, 106 may be the same or different. As used herein, the “thickness” of the pins 105 or 106 may refer to a cross-sectional dimension. In embodiments herein, the pins 105 may have a thickness or cross-sectional dimension of less than 100 um, which may be enabled by lithography-based manufacturing processes.

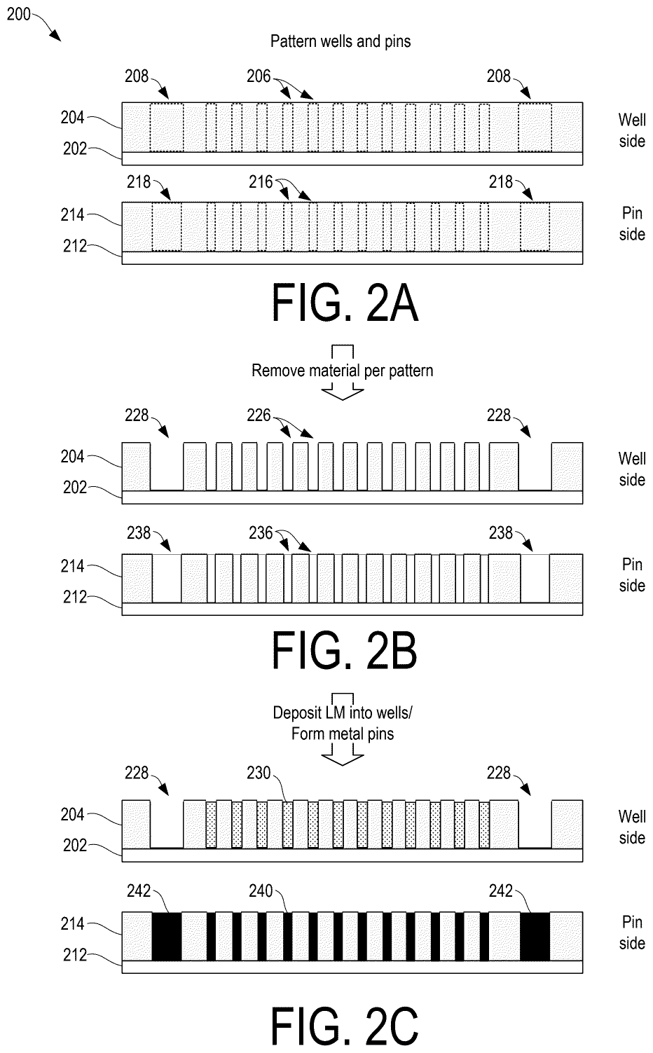

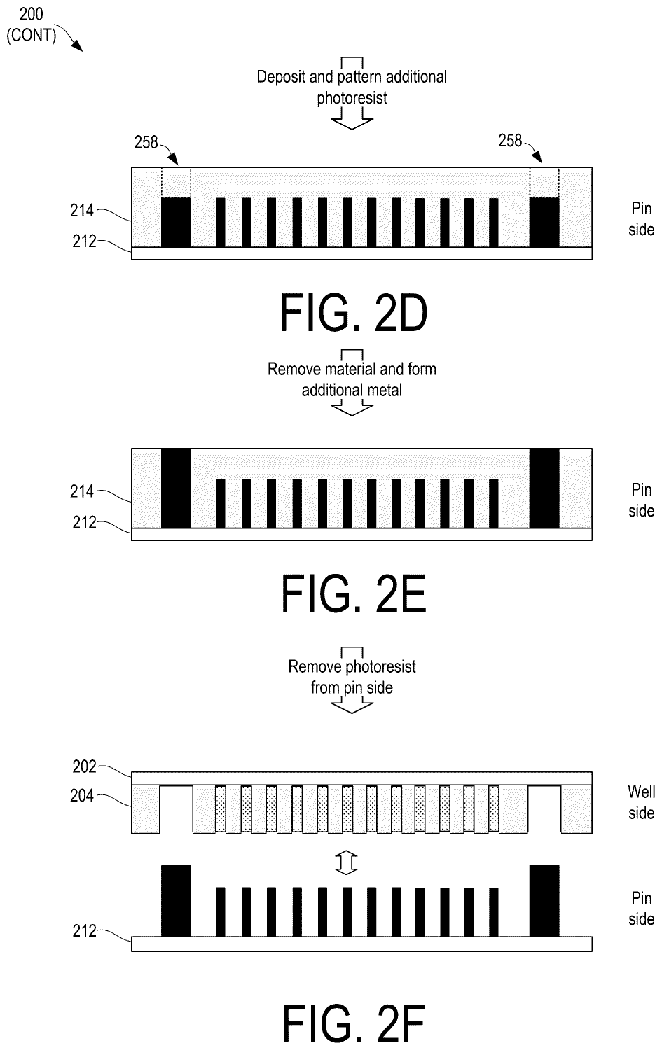

FIGS. 2A-2F illustrate an example lithography-based process 200 of manufacturing LM-based interconnect components in accordance with embodiments of the present disclosure. The process may include additional, fewer, or different operations than those shown or described below. Further, while the example process 200 shows the wells and the pins of the socket being fabricated in the same process, operations may be performed in a different order than shown, may be performed simultaneously when shown as separate operations, or may be performed as separate operations when shown as being performed simultaneously. In some embodiments, one or more of the operations shown include multiple operations, sub-operations, etc.

In the example process 200, photoresist layers 204, 214 are formed on substrates 202, 212, respectively. The photoresist layers 204, 214 may be formed via a spin-coating process over the substrates in certain embodiments. In certain embodiments, the substrate 202 may be the package substrate (e.g., the package substrate 112 of FIGS. 1A-1B) and the substrate 212 may be the substrate body of the LM-compatible socket (e.g., the socket 104 of FIGS. 1A-1B). That is, the wells may be formed directly onto the bottom of the package substrate as opposed to being formed separately then attached to the substrate thereafter, and the pins may be fabricated directly onto the socket body using the process 200 as opposed to the pins being stitched or inserted into the socket body as may be done currently.

Then, using a mask, the well areas 206, alignment pin cavity areas 208, pin locations 216, and alignment pin locations 218 are exposed and developed as shown in FIG. 2A, and the photoresist material in the areas 206, 208, 216, 218 can be removed as shown in FIG. 2B. The photoresist material can be removed by an etching or similar process. Then, as shown in FIG. 2C, a conductive material can be deposited on the pin side to form the contact pins 240 (which are for interconnecting with LM 230 in the wells 226) and alignment pins 242 (which are for providing alignment between the socket and package when the pins 242 are inserted into the cavities 228). This can be done via an electroplating process in certain embodiments. As shown, the alignment pins 242 may be wider than the contact pins 240 in certain embodiments. At the same or different time, LM 230 can be deposited into the wells 236 formed in the layer of photoresist material 214, while the alignment pin cavities 228 are left empty.

In some embodiments, the alignment pins 242 may be taller than the socket pins 240. Thus, as shown in FIGS. 2D-2E, additional lithography operations can be performed to add additional conductive material to the alignment pins. This is shown in FIG. 2D by the additional of another layer of photoresist material, followed by exposing, developing, and removing the material from the areas 258, and then depositing additional conductive material (e.g., via electroplating) as shown in FIG. 2E to add to the height of the alignment pins. The photoresist material 214 can then be removed as shown in FIG. 2F to yield a finished or closed to finished socket with alignment and contact pins. The components are then ready for attachment, e.g., as shown in FIG. 1B.

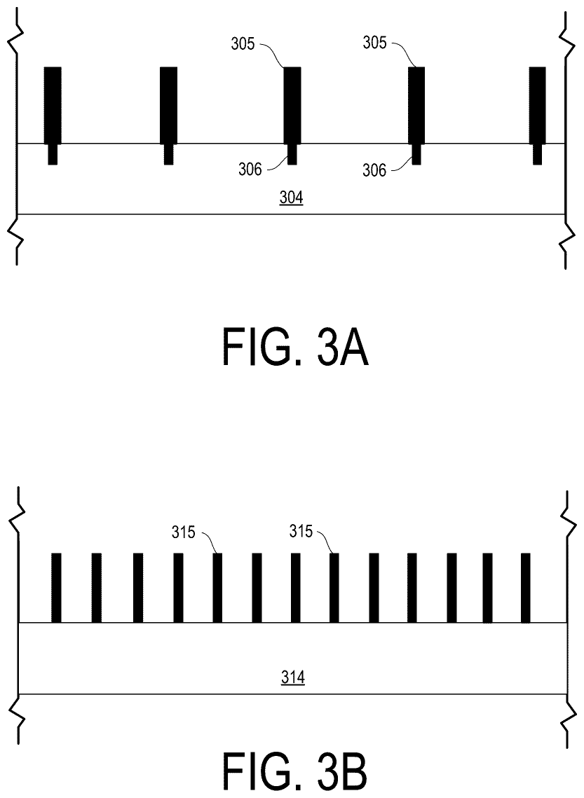

FIGS. 3A-3B illustrate the socket-pin interface for stitched contact pins 305 and lithographically-defined contact pins 345, respectively. As shown in FIG. 3B, the pins 305 are inserted into the socket substrate 304 during the stitching process, and thus, have a portion 306 that extends into the socket substrate 304. In contrast, the pins 315 are lithographically-defined as described above and formed via direct deposition onto the socket substrate 314. Accordingly, no portion of the pins 315 is within the substrate 314. Further, because the pins 315 are lithographically-defined as described herein, the pins 315 have a lower pitch (that is, distance between the pins 315) than the pins 305. In some embodiments, for example, pitch of the pins 315 may be less than 500 um, e.g., 400 um, 250 um, 100 um, or smaller. Indeed, using lithography-based processes, the pins 315 may be fabricated as 800 um tall pins with 50 um×30 um rectangular cross-sectional dimensions and 80 um pitch.

In certain embodiments, the pins 315 may also be formed with different materials than the pins 305. For example, the pins 305 may typically be formed with copper, brass, bronze, or C7250, but the Ga-based LM can corrode these materials, so the pins must be plated with a layer of nickel and/or a layer of gold to avoid corrosion. In embodiments herein, because the pins 315 are formed in a different manner, the material can be chosen to have reduced corrosion risk with respect to the Ga-based LM. As some examples, the pins 315 may be formed using nickel, gold, cobalt, chromium, titanium, iron, an iron-nickel alloy (NiFe), an alloy that includes cobalt, nickel and phosphorus (e.g., NiCoP), an alloy that includes nickel and gold (NiAu), or an alloy of any of the previous elements (e.g., C7250). Other materials can be used as well.

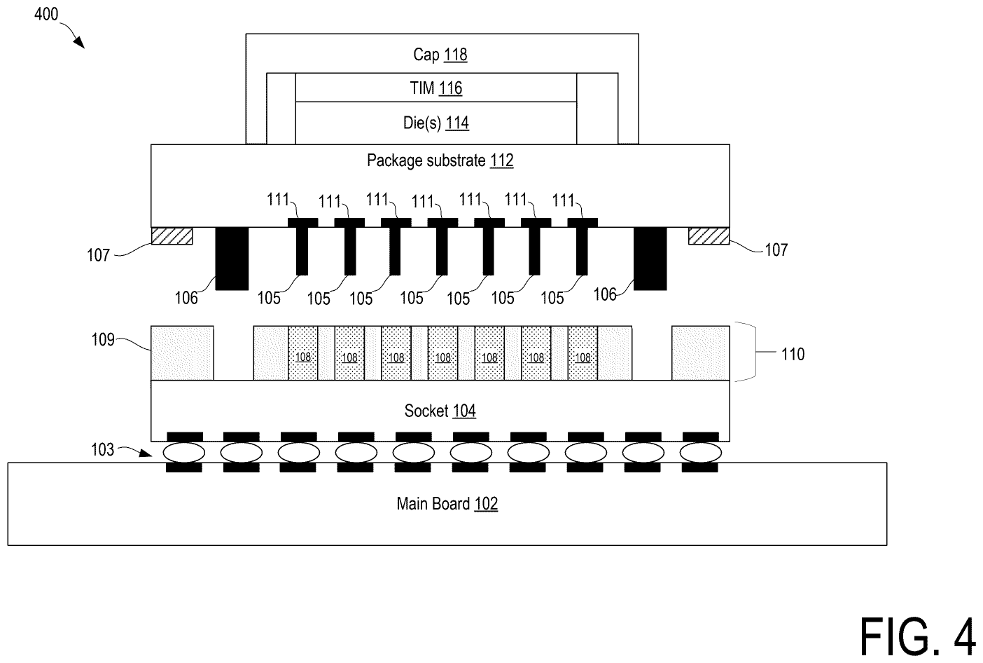

Although the examples above are described as having an LM interposer housing (e.g., 110) coupled to the bottom of a package substrate (e.g., 112) and a socket with pins, other embodiments of the present disclosure can be implemented with pins attached to the package substrate that are inserted into LM wells of a socket. FIG. 4 illustrates an alternate example of an integrated circuit device assembly in accordance with embodiments of the present disclosure. In particular, FIG. 4 il lustrates an assembly 400 that includes the same components as the assembly 100 of FIGS. 1A-1B, but with the LM wells 108 being in an interposer housing 110 that is coupled to the socket 104 instead of the package substrate 112. In addition, in the example shown, the pins 105, 106 and the seal material 107 is coupled to the package substrate 112 instead of the socket 104.

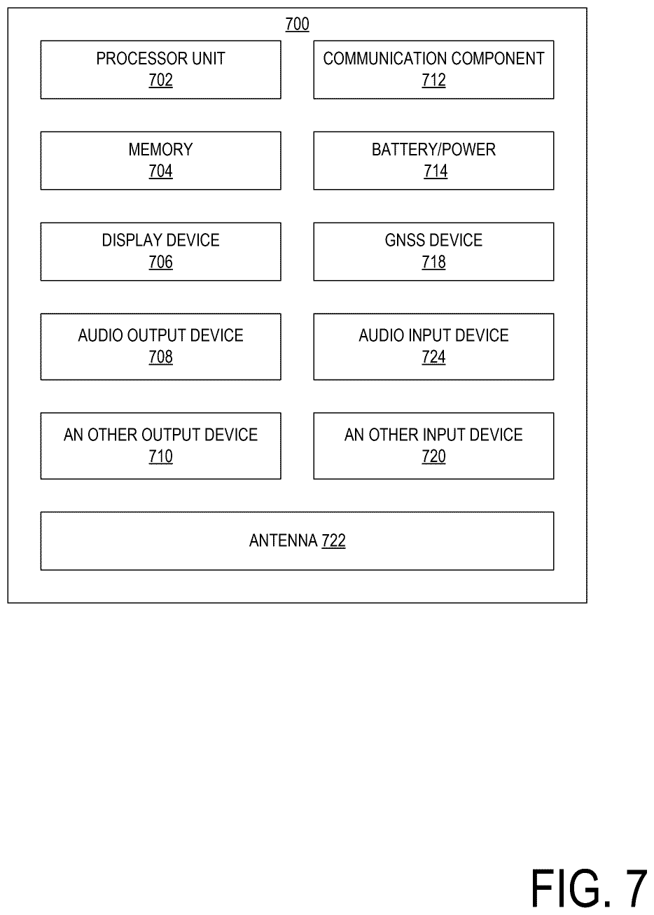

FIG. 5 is a top view of a wafer 500 and dies 502 that may incorporate any of the embodiments disclosed herein. The wafer 500 may be composed of semiconductor material and may include one or more dies 502 having integrated circuit structures formed on a surface of the wafer 500. The individual dies 502 may be a repeating unit of an integrated circuit product that includes any suitable integrated circuit. After the fabrication of the semiconductor product is complete, the wafer 500 may undergo a singulation process in which the dies 502 are separated from one another to provide discrete “chips” of the integrated circuit product. The die 502 may include one or more transistors (e.g., some of the transistors 640 of FIG. 6, discussed below), supporting circuitry to route electrical signals to the transistors, passive components (e.g., signal traces, resistors, capacitors, or inductors), and/or any other integrated circuit components. In some embodiments, the wafer 500 or the die 502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 502. For example, a memory array formed by multiple memory devices may be formed on a same die 502 as a processor unit (e.g., the processor unit 702 of FIG. 7) or other logic that is configured to store information in the memory devices or execute instructions stored in the memory array.

FIG. 6 is a cross-sectional side view of an integrated circuit device 600 that may be included in any of the embodiments disclosed herein. One or more of the integrated circuit devices 600 may be included in one or more dies 502 (FIG. 5). The integrated circuit device 600 may be formed on a die substrate 602 (e.g., the wafer 500 of FIG. 5) and may be included in a die (e.g., the die 502 of FIG. 5). The die substrate 602 may be a semiconductor substrate composed of semiconductor material systems including, for example, n-type or p-type materials systems (or a combination of both). The die substrate 602 may include, for example, a crystalline substrate formed using a bulk silicon or a silicon-on-insulator (SOI) substructure. In some embodiments, the die substrate 602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 602. Although a few examples of materials from which the die substrate 602 may be formed are described here, any material that may serve as a foundation for an integrated circuit device 600 may be used. The die substrate 602 may be part of a singulated die (e.g., the dies 502 of FIG. 5) or a wafer (e.g., the wafer 500 of FIG. 5).

The integrated circuit device 600 may include one or more device layers 604 disposed on the die substrate 602. The device layer 604 may include features of one or more transistors 640 (e.g., metal oxide semiconductor field-effect transistors (MOSFETs)) formed on the die substrate 602. The transistors 640 may include, for example, one or more source and/or drain (S/D) regions 620, a gate 622 to control current flow between the S/D regions 620, and one or more S/D contacts 624 to route electrical signals to/from the S/D regions 620. The transistors 640 may include additional features not depicted for the sake of clarity, such as device isolation regions, gate contacts, and the like. The transistors 640 are not limited to the type and configuration depicted in FIG. 6 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 6, a transistor 640 may include a gate 622 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 640 along the source-channel-drain direction, the gate electrode may consist of a U-shaped structure that includes a bottom portion substantially parallel to the surface of the die substrate 602 and two sidewall portions that are substantially perpendicular to the top surface of the die substrate 602. In other embodiments, at least one of the metal layers that form the gate electrode may simply be a planar layer that is substantially parallel to the top surface of the die substrate 602 and does not include sidewall portions substantially perpendicular to the top surface of the die substrate 602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 620 may be formed within the die substrate 602 adjacent to the gate 622 of individual transistors 640. The S/D regions 620 may be formed using an implantation/diffusion process or an etching/deposition process, for example. In the former process, dopants such as boron, aluminum, antimony, phosphorous, or arsenic may be ion-implanted into the die substrate 602 to form the S/D regions 620. An annealing process that activates the dopants and causes them to diffuse farther into the die substrate 602 may follow the ion-implantation process. In the latter process, the die substrate 602 may first be etched to form recesses at the locations of the S/D regions 620. An epitaxial deposition process may then be carried out to fill the recesses with material that is used to fabricate the S/D regions 620. In some implementations, the S/D regions 620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 620 may be formed using one or more alternate semiconductor materials such as germanium or a group III-V material or alloy. In further embodiments, one or more layers of metal and/or metal alloys may be used to form the S/D regions 620.

Electrical signals, such as power and/or input/output (I/O) signals, may be routed to and/or from the devices (e.g., transistors 640) of the device layer 604 through one or more interconnect layers disposed on the device layer 604 (illustrated in FIG. 6 as interconnect layers 606-610). For example, electrically conductive features of the device layer 604 (e.g., the gate 622 and the S/D contacts 624) may be electrically coupled with the interconnect structures 628 of the interconnect layers 606-610. The one or more interconnect layers 606-610 may form a metallization stack (also referred to as an “ILD stack”) 619 of the integrated circuit device 600.

The interconnect structures 628 may be arranged within the interconnect layers 606-610 to route electrical signals according to a wide variety of designs; in particular, the arrangement is not limited to the particular configuration of interconnect structures 628 depicted in FIG. 6. Although a particular number of interconnect layers 606-610 is depicted in FIG. 6, embodiments of the present disclosure include integrated circuit devices having more or fewer interconnect layers than depicted.

In some embodiments, the interconnect structures 628 may include lines 628a and/or vias 628b filled with an electrically conductive material such as a metal. The lines 628a may be arranged to route electrical signals in a direction of a plane that is substantially parallel with a surface of the die substrate 602 upon which the device layer 604 is formed. For example, the lines 628a may route electrical signals in a direction in and out of the page and/or in a direction across the page from the perspective of FIG. 6. The vias 628b may be arranged to route electrical signals in a direction of a plane that is substantially perpendicular to the surface of the die substrate 602 upon which the device layer 604 is formed. In some embodiments, the vias 628b may electrically couple lines 628a of different interconnect layers 606-610 together.

The interconnect layers 606-610 may include a dielectric material 626 disposed between the interconnect structures 628, as shown in FIG. 6. In some embodiments, dielectric material 626 disposed between the interconnect structures 628 in different ones of the interconnect layers 606-610 may have different compositions; in other embodiments, the composition of the dielectric material 626 between different interconnect layers 606-610 may be the same. The device layer 604 may include a dielectric material 626 disposed between the transistors 640 and a bottom layer of the metallization stack as well. The dielectric material 626 included in the device layer 604 may have a different composition than the dielectric material 626 included in the interconnect layers 606-610; in other embodiments, the composition of the dielectric material 626 in the device layer 604 may be the same as a dielectric material 626 included in any one of the interconnect layers 606-610.

A first interconnect layer 606 (referred to as Metal 1 or “M1”) may be formed directly on the device layer 604. In some embodiments, the first interconnect layer 606 may include lines 628a and/or vias 628b, as shown. The lines 628a of the first interconnect layer 606 may be coupled with contacts (e.g., the S/D contacts 624) of the device layer 604. The vias 628b of the first interconnect layer 606 may be coupled with the lines 628a of a second interconnect layer 608.

The second interconnect layer 608 (referred to as Metal 2 or “M2”) may be formed directly on the first interconnect layer 606. In some embodiments, the second interconnect layer 608 may include via 628b to couple the lines 628 of the second interconnect layer 608 with the lines 628a of a third interconnect layer 610. Although the lines 628a and the vias 628b are structurally delineated with a line within individual interconnect layers for the sake of clarity, the lines 628a and the vias 628b may be structurally and/or materially contiguous (e.g., simultaneously filled during a dual-damascene process) in some embodiments.

The third interconnect layer 610 (referred to as Metal 3 or “M3”) (and additional interconnect layers, as desired) may be formed in succession on the second interconnect layer 608 according to similar techniques and configurations described in connection with the second interconnect layer 608 or the first interconnect layer 606. In some embodiments, the interconnect layers that are “higher up” in the metallization stack 619 in the integrated circuit device 600 (i.e., farther away from the device layer 604) may be thicker that the interconnect layers that are lower in the metallization stack 619, with lines 628a and vias 628b in the higher interconnect layers being thicker than those in the lower interconnect layers.

The integrated circuit device 600 may include a solder resist material 634 (e.g., polyimide or similar material) and one or more conductive contacts 636 formed on the interconnect layers 606-610. In FIG. 6, the conductive contacts 636 are illustrated as taking the form of bond pads. The conductive contacts 636 may be electrically coupled with the interconnect structures 628 and configured to route the electrical signals of the transistor(s) 640 to external devices. For example, solder bonds may be formed on the one or more conductive contacts 636 to mechanically and/or electrically couple an integrated circuit die including the integrated circuit device 600 with another component (e.g., a printed circuit board or a package substrate, e.g., 112). The integrated circuit device 600 may include additional or alternate structures to route the electrical signals from the interconnect layers 606-610; for example, the conductive contacts 636 may include other analogous features (e.g., posts) that route the electrical signals to external components.

In some embodiments in which the integrated circuit device 600 is a double-sided die, the integrated circuit device 600 may include another metallization stack (not shown) on the opposite side of the device layer(s) 604. This metallization stack may include multiple interconnect layers as discussed above with reference to the interconnect layers 606-610, to provide conductive pathways (e.g., including conductive lines and vias) between the device layer(s) 604 and additional conductive contacts (not shown) on the opposite side of the integrated circuit device 600 from the conductive contacts 636.

In other embodiments in which the integrated circuit device 600 is a double-sided die, the integrated circuit device 600 may include one or more through silicon vias (TSVs) through the die substrate 602; these TSVs may make contact with the device layer(s) 604, and may provide conductive pathways between the device layer(s) 604 and additional conductive contacts (not shown) on the opposite side of the integrated circuit device 600 from the conductive contacts 636. In some embodiments, TSVs extending through the substrate can be used for routing power and ground signals from conductive contacts on the opposite side of the integrated circuit device 600 from the conductive contacts 636 to the transistors 640 and any other components integrated into the die 600, and the metallization stack 619 can be used to route I/O signals from the conductive contacts 636 to transistors 640 and any other components integrated into the die 600.

Multiple integrated circuit devices 600 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

FIG. 7 is a block diagram of an example electrical device 700 that may include one or more of the embodiments disclosed herein. For example, any suitable ones of the components of the electrical device 700 may include one or more of assemblies 100, integrated circuit devices 600, or integrated circuit dies 502 disclosed herein. A number of components are illustrated in FIG. 7 as included in the electrical device 700, but any one or more of these components may be omitted or duplicated, as suitable for the application. In some embodiments, some or all of the components included in the electrical device 700 may be attached to one or more motherboards mainboards, or system boards. In some embodiments, one or more of these components are fabricated onto a single system-on-a-chip (SoC) die.

Additionally, in various embodiments, the electrical device 700 may not include one or more of the components illustrated in FIG. 7, but the electrical device 700 may include interface circuitry for coupling to the one or more components. For example, the electrical device 700 may not include a display device 706, but may include display device interface circuitry (e.g., a connector and driver circuitry) to which a display device 706 may be coupled. In another set of examples, the electrical device 700 may not include an audio input device 724 or an audio output device 708, but may include audio input or output device interface circuitry (e.g., connectors and supporting circuitry) to which an audio input device 724 or audio output device 708 may be coupled.

The electrical device 700 may include one or more processor units 702 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 702 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 700 may include a memory 704, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 704 may include memory that is located on the same integrated circuit die as the processor unit 702. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 700 can comprise one or more processor units 702 that are heterogeneous or asymmetric to another processor unit 702 in the electrical device 700. There can be a variety of differences between the processing units 702 in a system in terms of a spectrum of metrics of merit including architectural, microarchitectural, thermal, power consumption characteristics, and the like. These differences can effectively manifest themselves as asymmetry and heterogeneity among the processor units 702 in the electrical device 700.

In some embodiments, the electrical device 700 may include a communication component 712 (e.g., one or more communication components). For example, the communication component 712 can manage wireless communications for the transfer of data to and from the electrical device 700. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 712 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 712 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 712 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 712 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 712 may operate in accordance with other wireless protocols in other embodiments. The electrical device 700 may include an antenna 722 to facilitate wireless communications and/or to receive other wireless communications (such as AM or FM radio transmissions).

In some embodiments, the communication component 712 may manage wired communications, such as electrical, optical, or any other suitable communication protocols (e.g., IEEE 802.3 Ethernet standards). As noted above, the communication component 712 may include multiple communication components. For instance, a first communication component 712 may be dedicated to shorter-range wireless communications such as Wi-Fi or Bluetooth, and a second communication component 712 may be dedicated to longer-range wireless communications such as global positioning system (GPS), EDGE, GPRS, CDMA, WiMAX, LTE, EV-DO, or others. In some embodiments, a first communication component 712 may be dedicated to wireless communications, and a second communication component 712 may be dedicated to wired communications.

The electrical device 700 may include battery/power circuitry 714. The battery/power circuitry 714 may include one or more energy storage devices (e.g., batteries or capacitors) and/or circuitry for coupling components of the electrical device 700 to an energy source separate from the electrical device 700 (e.g., AC line power).

The electrical device 700 may include a display device 706 (or corresponding interface circuitry, as discussed above). The display device 706 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 700 may include an audio output device 708 (or corresponding interface circuitry, as discussed above). The audio output device 708 may include any embedded or wired or wirelessly connected external device that generates an audible indicator, such speakers, headsets, or earbuds.

The electrical device 700 may include an audio input device 724 (or corresponding interface circuitry, as discussed above). The audio input device 724 may include any embedded or wired or wirelessly connected device that generates a signal representative of a sound, such as microphones, microphone arrays, or digital instruments (e.g., instruments having a musical instrument digital interface (MIDI) output). The electrical device 700 may include a Global Navigation Satellite System (GNSS) device 718 (or corresponding interface circuitry, as discussed above), such as a Global Positioning System (GPS) device. The GNSS device 718 may be in communication with a satellite-based system and may determine a geolocation of the electrical device 700 based on information received from one or more GNSS satellites, as known in the art.

The electrical device 700 may include another output device 710 (or corresponding interface circuitry, as discussed above). Examples of the other output device 710 may include an audio codec, a video codec, a printer, a wired or wireless transmitter for providing information to other devices, or an additional storage device.

The electrical device 700 may include another input device 720 (or corresponding interface circuitry, as discussed above). Examples of the other input device 720 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 700 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 700 may be any other electronic device that processes data. In some embodiments, the electrical device 700 may comprise multiple discrete physical components. Given the range of devices that the electrical device 700 can be manifested as in various embodiments, in some embodiments, the electrical device 700 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is an apparatus comprising: a substrate; conductive contacts on a first side of the substrate; first metal pins extending from a second side of the substrate opposite the first side, wherein a distance between centers of neighboring first metal pins is less than 500 μm; and second metal pins extending from the second side of the substrate, the second metal pins extending further from the substrate than the first metal pins.

Example 2 includes the subject matter of Example 1, wherein a cross-sectional dimension of the first metal pins is under 100 um.

Example 3 includes the subject matter of Example 1 or 2, wherein no portion of the first metal pins is within the substrate.

Example 4 includes the subject matter of any one of Examples 1-3, wherein a cross-sectional dimension of the second metal pins is greater than a cross-sectional dimension of the first metal pins.

Example 5 includes the subject matter of any one of Examples 1-4, wherein the second metal pins are outside an area of the first metal pins.

Example 6 includes the subject matter of any one of Examples 1-5, further comprising a seal material on the second side of the substrate, the seal material surrounding the first metal pins and the second metal pins.

Example 7 includes the subject matter of any one of Examples 1-6, wherein the first metal pins comprise one or more of nickel, gold, cobalt, chromium, titanium, iron, and phosphorus.

Example 8 includes the subject matter of any one of Examples 1-7, wherein the substrate comprises an epoxy-based material.

Example 9 includes the subject matter of any one of Examples 1-8, wherein the first metal pins are in electrical connection with the conductive contacts through the substrate.

Example 10 includes the subject matter of any one of Examples 1-9, further comprising a circuit board coupled to the first side of the substrate, and solder balls connected between respective pairs of conductive contacts of the substrate and conductive contacts of the circuit board.

Example 11 includes the subject matter of any one of Examples 1-10, further comprising an integrated circuit device assembly, wherein the integrated circuit device assembly comprises: a substrate; an integrated circuit die coupled to the substrate; and Gallium-based liquid metal in wells on an opposite side of the substrate than the integrated circuit die; and wherein the first metal pins are in contact with the liquid metal in the wells.

Example 12 is an apparatus comprising: a substrate comprising conductive contacts on a first side of the substrate; a layer defining holes around respective conductive contacts of the substrate, wherein a distance between centers of neighboring holes is less than 500 μm; and Gallium-based liquid metal in each hole, the liquid metal in contact with the conductive contact in the hole.

Example 13 includes the subject matter of Example 12, wherein the holes are first holes, and the layer further defines second holes, the second holes having a cross-sectional dimension that is larger than a cross-sectional dimension of the first holes.

Example 14 includes the subject matter of Example 12 or 13, wherein the layer comprises a photoresist material.

Example 15 includes the subject matter of any one of Examples 12-14, further comprising an integrated circuit device coupled to a second side of the substrate opposite the first side.

Example 16 includes the subject matter of Example 15, further comprising: a circuit board; and a socket coupled to the circuit board, the socket comprising metal pins extending from a side of the socket opposite the circuit board, the metal pins in contact with the Gallium-based liquid metal.

Example 17 is a system comprising: a circuit board; a socket coupled to the circuit board, the socket comprising: metal pins extending from a side of the socket opposite the circuit board, wherein a distance between centers of neighboring metal pins is less than 500 um; and an integrated circuit device assembly coupled to the socket, the integrated circuit device assembly comprising: a substrate; an integrated circuit die coupled to a first side of the substrate; wells defined on a second side of the substrate opposite the first side, the wells defined around respective conductive contacts of the substrate; and Gallium-based liquid metal in the wells, the liquid metal in contact with the conductive contacts; wherein the metal pins of the socket are in contact with the liquid metal in the wells.

Example 18 includes the subject matter of Example 17, wherein the metal pins are first metal pins and the socket further comprises second metal pins extending from the side of the socket opposite the circuit board into holes of the integrated circuit device assembly, the second metal pins taller than the first metal pins.

Example 19 includes the subject matter of Example 17 or 18, wherein a cross-sectional dimension of the first metal pins is under 100 um.

Example 20 includes the subject matter of any one of Examples 17-19, wherein no portion of the first metal pins is within the substrate.

Example 21 includes the subject matter of Example 18, wherein a cross-sectional dimension of the second metal pins is greater than a cross-sectional dimension of the first metal pins.

Example 22 includes the subject matter of Example 18 or 21, wherein the second metal pins are outside an area of the first metal pins.

Example 23 includes the subject matter of any one of Examples 17-22, further comprising a seal material on the side of the socket opposite the circuit board, the seal material surrounding the metal pins.

Example 24 includes the subject matter of any one of Examples 17-23, wherein the metal pins comprise one or more of nickel, gold, cobalt, chromium, titanium, iron, and phosphorus.

Example 25 includes the subject matter of any one of Examples 17-24, wherein the socket comprises an epoxy-based material.

Example 26 includes the subject matter of any one of Examples 17-25, wherein the metal pins are in electrical connection with the circuit board through the socket.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

Further, concepts described herein are illustrated by way of example and not by way of limitation in the accompanying Figures. For simplicity and clarity of illustration, elements illustrated in the Figures might not be necessarily drawn to scale. Where considered appropriate, reference labels may have been repeated between certain Figures to indicate corresponding or analogous elements.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. An apparatus comprising:
a substrate;
conductive contacts on a first side of the substrate;
first metal pins extending from a second side of the substrate opposite the first side, wherein a distance between centers of neighboring first metal pins is less than 500 um; and
second metal pins extending from the second side of the substrate, the second metal pins extending further from the substrate than the first metal pins.

2. The apparatus of claim 1, wherein a cross-sectional dimension of the first metal pins is under 100 um.

3. The apparatus of claim 1, wherein no portion of the first metal pins is within the substrate.

4. The apparatus of claim 1, wherein a cross-sectional dimension of the second metal pins is greater than a cross-sectional dimension of the first metal pins.

5. The apparatus of claim 1, wherein the second metal pins are outside an area of the first metal pins.

6. The apparatus of claim 1, further comprising a seal material on the second side of the substrate, the seal material surrounding the first metal pins and the second metal pins.

7. The apparatus of claim 1, wherein the first metal pins comprise one or more of nickel, gold, cobalt, chromium, titanium, iron, and phosphorus.

8. The apparatus of claim 1, wherein the substrate comprises an epoxy-based material.

9. The apparatus of claim 1, wherein the first metal pins are in electrical connection with the conductive contacts through the substrate.

10. The apparatus of claim 1, further comprising a circuit board coupled to the first side of the substrate, and solder balls connected between respective pairs of conductive contacts of the substrate and conductive contacts of the circuit board.

11. The apparatus of claim 1, further comprising an integrated circuit device assembly, wherein the integrated circuit device assembly comprises:
a substrate;
an integrated circuit die coupled to the substrate; and
Gallium-based liquid metal in wells on an opposite side of the substrate than the integrated circuit die; and
wherein the first metal pins are in contact with the liquid metal in the wells.

12. An apparatus comprising:
a substrate comprising conductive contacts on a first side of the substrate;
a layer defining holes around respective conductive contacts of the substrate, wherein a distance between centers of neighboring holes is less than 500 um; and
Gallium-based liquid metal in each hole, the liquid metal in contact with the conductive contact in the hole.

13. The apparatus of claim 12, wherein the holes are first holes, and the layer further defines second holes, the second holes having a cross-sectional dimension that is larger than a cross-sectional dimension of the first holes.

14. The apparatus of claim 12, further comprising an integrated circuit device coupled to a second side of the substrate opposite the first side.

15. A system comprising:
a circuit board;
a socket coupled to the circuit board, the socket comprising:
metal pins extending from a side of the socket opposite the circuit board, wherein a distance between centers of neighboring metal pins is less than 500 um; and
an integrated circuit device assembly coupled to the socket, the integrated circuit device assembly comprising:
a substrate;
an integrated circuit die coupled to a first side of the substrate;
wells defined on a second side of the substrate opposite the first side, the wells defined around respective conductive contacts of the substrate; and
Gallium-based liquid metal in the wells, the liquid metal in contact with the conductive contacts;
wherein the metal pins of the socket are in contact with the liquid metal in the wells.

16. The system of claim 15, wherein the metal pins are first metal pins and the socket further comprises second metal pins extending from the side of the socket opposite the circuit board into holes of the integrated circuit device assembly, the second metal pins taller than the first metal pins.

17. The system of claim 15, wherein a cross-sectional dimension of the metal pins is under 100 um.

18. The system of claim 15, further comprising a seal material on the side of the socket opposite the circuit board, the seal material surrounding the metal pins.

19. The system of claim 15, wherein the metal pins comprise one or more of nickel, gold, cobalt, chromium, titanium, iron, and phosphorus.

20. The system of claim 15, wherein the socket comprises an epoxy-based material.
